(19) United States
(12) Patent Application Publication
(10) Pub. No.: US 2008/0170378 A1
(43) Pub. Date: Jul. 17, 2008

(54) CIRCUIT STRUCTURE HAVING INDEPENDENT GROUND PLANE LAYOUTS IMPLEMENTED IN CIRCUIT BOARD

(76) Inventor: Cheng-Yi Ou-Yang, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 11/769,711

(22) Filed: Jun. 28, 2007

Related U.S. Application Data
(60) Provisional application No. 60/885,385, filed on Jan. 17, 2007.

(51) Int. Cl. H05K 1/02

(52) U.S. Cl. 361/799

(57) ABSTRACT

A circuit structure includes a circuit board, a first circuit component mounted on the circuit board, and a second circuit component mounted on the circuit board. The first circuit board has a first ground plane layout including at least one ground plane, and a second ground plane layout including at least one ground plane, where the first ground plane layout is not electrically connected to the second ground plane layout within the circuit board. The first circuit component is electrically connected to the first ground plane layout, and the second circuit component is electrically connected to the second ground plane layout.

### CROSS REFERENCE TO RELATED APPLICATIONS

This application claims the benefit of U.S. Provisional Application No. 60/885,385, filed on Jan. 17, 2007 and included herein by reference.

### BACKGROUND

The present invention relates to a circuit board design, and more particularly, to a circuit structure having independent ground plane layouts implemented in a circuit board for respective circuit components, such as a GPS IC and a TCXO.

In general, circuit components are mounted on a circuit board (e.g., a printed circuit board, PCB) and interconnected through the conductive paths routed on the circuit board. Taking the receiver design of a global navigation satellite system (GNSS), such as a global positioning system (GPS), as an example, the GPS receiver includes a GPS IC for processing radio-frequency signals and base-band signals for computing the position information and an oscillator (e.g., a temperature compensation crystal oscillator) acting as a reference clock source with high frequency accuracy. That is, the GPS IC operates according to a reference oscillating signal generated from the oscillator through conductive connections defined by a circuit board design on which the GPS IC and the oscillator are both mounted. As the positioning performance of the GPS receiver greatly depends on the frequency accuracy of the oscillator, it is desired to make the reference oscillating signal of the oscillator as stable as possible. Even though a temperature compensation crystal oscillator is commonly implemented as the needed reference clock source, it is still very sensitive to ambient temperature variation which could cause the actual frequency to deviate from the target frequency. That is, the reference oscillating signal generated by the temperature compensation crystal oscillator has a frequency drift when the ambient temperature has any change. Consequently, the performance of the GPS receiver is degraded.

In a conventional design, the GPS IC and the temperature compensation crystal oscillator are designed to have a common ground plane disposed on the circuit board; however, this typical ground plane configuration could be a cause of the ambient temperature variation because the common ground plane is commonly made by metal material of high thermal conductivity, such as copper. For example, regarding the hand-held device equipped with the GPS receiver, such as a cellular phone or portable navigation device (PND), the power/current consumption is a serious issue for the hand-held device which generally uses the battery as its power supply source. To extend the operation time of the hand-held device, the GPS IC is configured to switch between a fully active mode and a power-saving mode (or a sleep mode), if the power-saving function is enabled. Since the current consumption under the fully active mode is different from that under the power-saving mode, the heat produced by the GPS IC operating under the fully active mode therefore differs from that produced by the GPS IC operating under the power-saving mode. In other words, the amount of heat dissipated from the GPS IC to the oscillator under the fully active mode is different from that dissipated from the GPS IC to the oscillator under the power-saving mode. As a result, a frequency drift of the reference oscillating signal produced by the oscillator occurs due to the ambient temperature change induced by the variation of heat transferred to the oscillator from the GPS IC through the common ground plane. In general, the temperature compensation crystal oscillator includes a typical crystal oscillator and a compensation circuit used to stabilize the oscillating frequency of the crystal oscillator. However, the compensation circuit of the temperature compensation crystal oscillator is unable to efficiently stabilize the outputted reference oscillating signal for the very small temperature change due to the inherent non-linear compensation characteristics. Additionally, the amount of the frequency drift caused by switching between the fully active mode and the power-saving mode still falls in the range defined by hardware specification of the temperature compensation crystal oscillator, so the practical and cost-efficient way to solve this problem is to prevent or alleviate the heat transfer induced by the GPS IC or other ICs mounted on the same circuit board from affecting the temperature compensation crystal oscillator via the common ground plane, instead of improving the compensation characteristic of the temperature compensation crystal oscillator. In short, to improve the performance of the GPS IC, it is desired to provide a novel and cost-efficient solution to solve the above-mentioned frequency drift problem.

### SUMMARY

It is therefore one of the objectives of the present invention to provide a circuit structure having independent ground plane layouts implemented in a circuit board for respective circuit components, such as a GPS IC and a TCXO.

According to one embodiment of the present invention, a circuit structure is provided. A circuit structure includes a circuit board having a first ground plane layout comprising at least one ground plane, and a second ground plane layout comprising at least one ground plane. The first ground plane layout is not electrically connected to the second ground plane layout within the first circuit board.

According to another embodiment of the present invention, a circuit structure is provided. The circuit structure includes a circuit board and at least a passive component. The circuit board includes a first ground plane layout comprising at least one ground layer, and a second ground plane layout comprising at least one ground layer. The first ground plane layout is not electrically connected to the second ground plane within the circuit board. The passive component is mounted on the circuit board, and used for electrically connecting the first ground plane layout to the second ground plane layout.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view illustrating an exemplary arrangement of ground plane layouts and circuit components of a circuit structure according to a module design of the present invention.

FIG. 2 is a section view along line 1-1′ of the circuit structure shown in FIG. 1.

FIG. 3 is a top view illustrating a circuit structure having the module shown in FIG. 1 mounted on a carrier board according to an embodiment of the present invention.

FIG. 4 is section view along line 3-3′ of the circuit structure shown in FIG. 3.

FIG. 5 is a diagram illustrating a first alternative embodiment of the module design.

FIG. 6 is a diagram illustrating a second alternative embodiment of the module design.

FIG. 7 is a diagram illustrating a third alternative embodiment of the module design.

FIG. 8 is a diagram illustrating a fourth alternative embodiment of the module design.

FIG. 9 is a top view illustrating an arrangement of ground planes and circuit components of an exemplary circuit structure according to a COB design of the present invention.

FIG. 10 is a section view along line 9-9′ of the circuit structure shown in FIG. 9.

FIG. 11 is a diagram illustrating an alternative circuit structure applied to a COB design.

FIG. 12 is a diagram illustrating yet another alternative circuit structure applied to a COB design.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

The present invention brings up a novel and cost-efficient solution to protect one reference clock source (e.g., an oscillator) from affected by heat dissipated from other circuit components (e.g., integrated circuits) by allocating a dedicated ground plane layout in a circuit board to the reference clock source. Further description is given in detail as below.

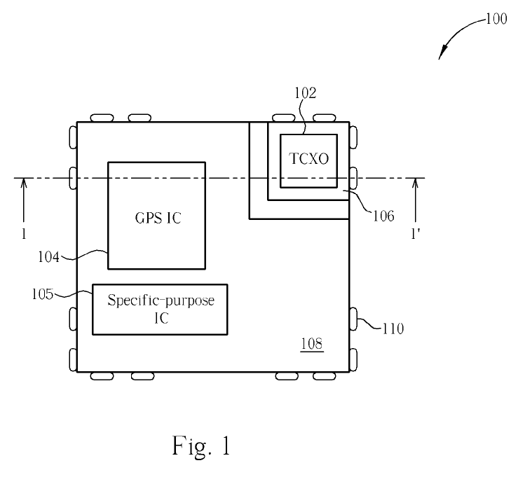

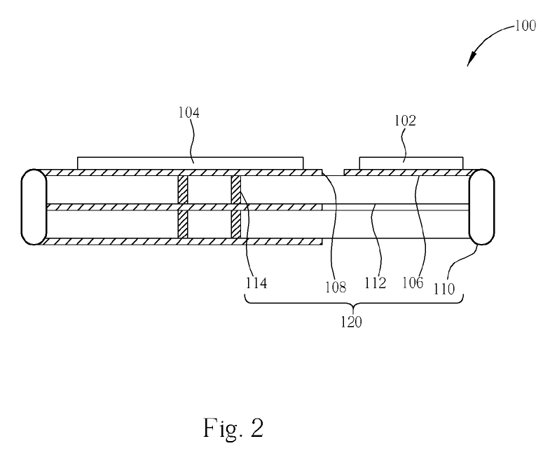

Please refer to FIG. 1 in conjunction with FIG. 2. FIG. 1 is a top view illustrating an exemplary arrangement of the ground plane layouts and circuit components of a circuit structure 100 according to a module design of the present invention. FIG. 2 is a section view along line 1-1′ of the circuit structure 100 shown in FIG. 1. As shown in FIG. 1 and FIG. 2, the exemplary circuit structure 100 is a module including a circuit board 120 and a plurality of circuit components mounted thereon. For illustrative purposes, the circuit components mounted on the circuit board 120 include, but not limited to, a signal processor of a global navigation satellite system (GNSS), such as a GPS IC 104, at least one optional specific-purpose IC 105 for performing other pre-defined functionality, and an oscillator for providing a reference clock referenced by the signal processor, such as a temperature compensation crystal oscillator (TCXO) 102. In this embodiment, the circuit board 120 is a multi-layer circuit board including a plurality of layers 112 and a plurality of ground plane layouts. One ground plane layout dedicated to the TCXO 102 includes a ground plane 106 formed on one surface of a specific layer in the circuit board 120, while the other ground plane layout commonly used by other circuit components, including the GPS IC 104 and the specific-purpose IC 105, has a plurality of ground planes 108 formed on one surface of a specific layer in the circuit board 120. As one can see, the ground planes 108 are electrically connected to each other through the conductive via holes 114. In addition, a plurality of soldering points 110 are used for mounting the module (i.e., the circuit structure 100) to a carrier board and providing needed electrical connections between the module and the carrier board. Since the composition of the circuit board is well known to those skilled in this art, further explanation is omitted here for the sake of brevity.

It should be noted that only the elements pertinent to the present invention are shown. For example, in FIG. 1 and FIG. 2, only ground planes are depicted; however, a skilled person will readily appreciate that the circuit board 120 also includes signal and power traces (not shown) routed on the surfaces of layers 112 and associated via holes (not shown) formed in the layers 112 to make the circuit components work normally when the module operates. Additionally, the size, number, and shape of the ground planes 106, 108 defined in the ground plane layouts for the TCXO 102, the GPS IC 104, and the specific-purpose IC 105 are for illustrative purposes only, and are not meant to be limitations of the present invention.

As one can see, the ground plane 106 on the circuit board 120 is dedicated to the TCXO 102, and is not directly connected to the ground plane 108 of the GPS IC 104. More specifically, in this embodiment there is no electrical connection or direct contact between the ground planes 106 and 108. Therefore, the ground plane 106 in the circuit board 120 is isolated from the ground plane 108 commonly used by the GPS IC 104 and other circuit components (e.g., the specific-purpose IC 105). In this way, the heat generated by the GPS IC 106 and other circuit components (e.g., the specific-purpose IC 105) is blocked from being transferred from the ground plane 108 to the ground plane 106 due to the gap between the ground plane 106 of the ground plane layout dedicated to the TCXO 102 and the ground plane 108 of the other ground plane layout commonly used by the GPS IC 104 and other circuit components (e.g., the specific-purpose IC 105). As a result, compared to the conventional circuit board design with a single common ground plane, the TCXO 102, which has a dedicated ground plane layout independent of the common ground plane layout of other circuit components, can operate at a more stable environment, and the frequency drift is minimized accordingly. In short, one key feature of the above exemplary module design is to block the dedicated ground plane 106 from being electrically connected to the common ground plane 108 within the same circuit board 120. In this way, the conventional heat transfer path established between the TCXO and the GPS IC due to the common ground plane is completely cut off.

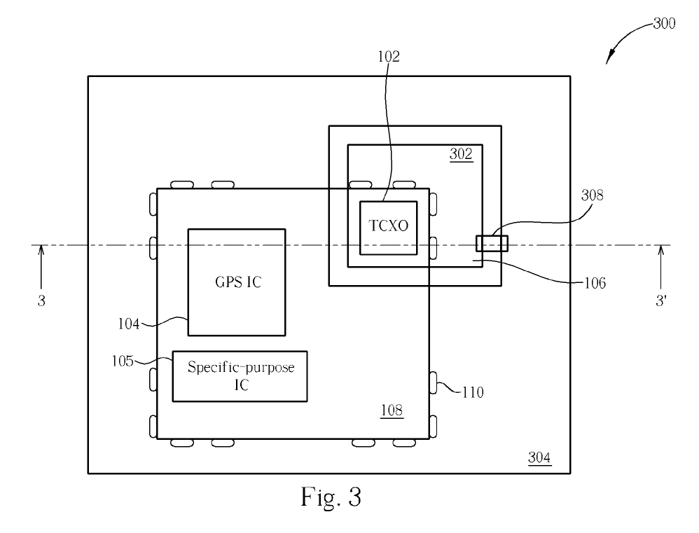

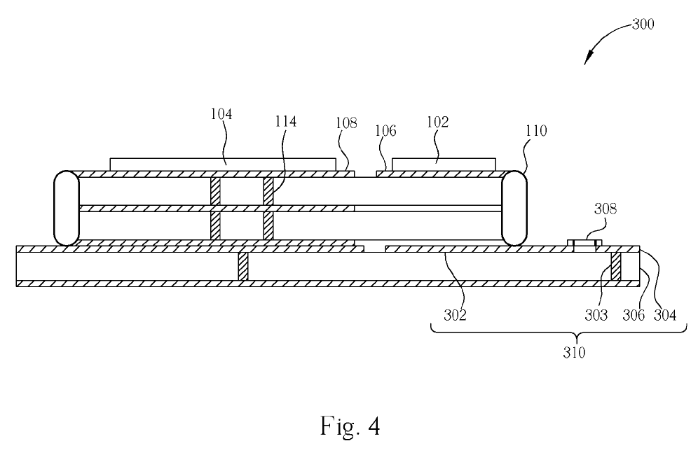

As shown in FIG. 1 and FIG. 2, the circuit structure 100 is to build a GPS module which contains soldering points 110 used for mounting the GPS module to another circuit board (i.e., a carrier board). Please refer to FIG. 3 in conjunction with FIG. 4. FIG. 3 is a top view illustrating a circuit structure 300 having the module shown in FIG. 1 mounted on a carrier board according to an embodiment of the present invention. FIG. 4 is section view along line 3-3′ of the circuit structure 300 shown in FIG. 3. The circuit structure 300 has the module shown in FIG. 1 mounted on a carrier board. That is, the circuit structure 100 mentioned above is mounted on another circuit board 310 through the soldering points 110. As shown in FIG. 3 and FIG. 4, the exemplary carrier board (i.e., the circuit board 310) has one ground plane layout independent of the other ground plane layout. More specifically, two ground planes 302 and 304 belonging to independent ground plane layouts are formed on a layer 306 of the circuit board 310. Additionally, there are via holes 303 in the layer 306 for providing required electrical connections. Similarly, as the composition of the circuit board is well known to those skilled in this art, further description is omitted here for brevity.

As one can see, the ground plane 302 is not directly connected to the adjacent ground plane 304. Therefore, a passive component 308 is mounted on the circuit board 310 to electrically connect the ground planes 302 and 304. In this way, a ground pin (not shown) of the TCXO 102 is electrically connected to a ground voltage through the ground planes 106, 302, 304 and the soldering point 110. In this embodiment, the passive component 308 provides a current loop of high frequency signal generated from the TCXO 102, and could be implemented by a resistor of any resistance value including 0 ohm, or a low AC impedance inductor (i.e., a high frequency inductor). It should be noted that the number and the position of the passive component 308 shown in FIG. 3 are for illustrative purposes only, and are not meant to be limitations of the present invention.

As the ground plane 302 is connected to the ground plane 304 via the passive component 308 instead of a direct metal contact, the heat transferred from the ground plane 304, which is electrically to other circuit components (e.g., the GPS IC 104 and the specific-purpose IC 105) through the via holes 303, to the ground plane 302, which is not directly connected to the ground plane 304, is totally or partially blocked by the passive component 308 due to its low thermal conductivity. In this way, the TCXO 102 is protected from the thermal disturbance caused by heat transferred through ground planes 108, 304 and respective via holes 114, 303. Briefly summarized, the stability of the TCXO 102 is maintained with minimum frequency drift. Please note that, based upon above disclosure, the via holes electrically connecting the ground plane layout having the ground plane 302 to the other ground plane layout having the ground plane 304 are prohibited; otherwise, the TCXO still suffers the thermal disturbance generated from other circuit components.

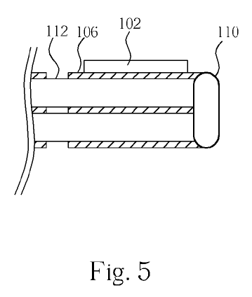

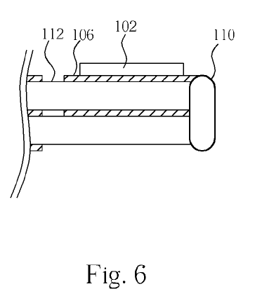

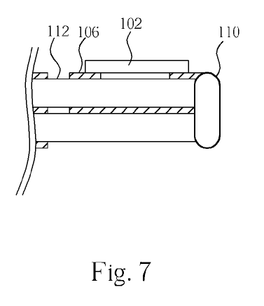

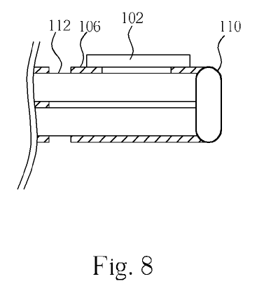

Furthermore, as shown in FIG. 2 and FIG. 4, the ground planes beneath the ground plane 106 of the ground plane layout dedicated to the TCXO 102 are removed to further block the heat transfer from other circuit components (e.g., the GPC IC 104 and the specific-purpose IC 105) from affecting the TCXO 102. That is, in this embodiment, the circuit board 120 has no ground plane overlapped with the dedicated ground plane 102 in the thickness direction of the circuit board 120 is disposed, thereby achieving an optimal thermal isolation effect. However, the present invention is not limited to remove all of the ground planes overlapped with the dedicated ground plane 106 in the thickness direction of the circuit board 120. Other alternative designs are possible. For example, in another embodiment, the ground planes overlapped with the dedicated ground plane 106 in the thickness direction of the circuit board 120 are formed but are not directly connected or electrically connected to the ground plane 104 belonging to the common ground plane layout of other circuit components. In this way, the ground planes beneath the dedicated ground plane 106 can help to dissipate heat generated by the TCXO 102. In yet another embodiment, the circuit board 120 is configured to have one or more specific layers on which no ground plane overlapped with the dedicated ground plane 106 in the thickness direction of the circuit board 120 is disposed. In other words, the number of removed ground planes depends upon design requirements. Moreover, the ground plane 106 is allowed to have an inner hollow region covered by the TCXO 102 to thereby offer further thermal isolation. Based on above description, certain exemplary drawings of alternative designs of the present invention are shown in FIGS. 5-8 respectively. It should be noted only those parts of the circuit structure pertinent to illustrating features of the alternative designs are shown. For example, the signal traces, power traces, and via holes are not depicted for simplicity. Additionally, these examples are for illustrative purposes only, and are not meant to be limitations of the present invention. Any modifications not departing from the spirit of the present invention still fall in the scope of the present invention.

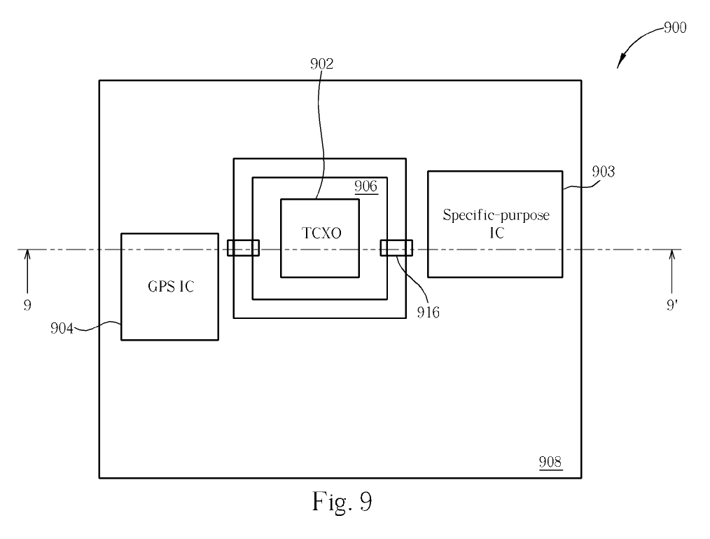

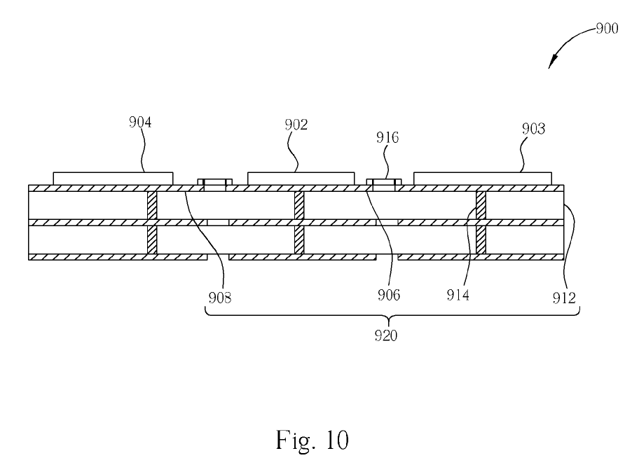

The above disclosure teaches a solution suitable for a module design. However, the similar thermal isolation scheme can be applied to a chip-on-board (COB) design as well. Please refer to FIG. 9 in conjunction with FIG. 10. FIG. 9 is a top view illustrating an arrangement of ground planes and circuit components of an exemplary circuit structure 900 according to a COB design of the present invention. FIG. 10 is a section view along line 9-9′ of the circuit structure 900 shown in FIG. 9. For illustrative purposes, the circuit components mounted on the circuit board 120 include, but not limited to, a signal processor of a global navigation satellite system (GNSS), such as a GPS IC 904, an oscillator for providing a reference oscillating signal referenced by the signal processor, such as a TCXO 902, and a specific-purpose IC 903 having a pre-defined operation and functionality. In this embodiment, the circuit board 920 is a multi-layer circuit board including a plurality of layers 912, a plurality of ground planes 906, 908 formed on surfaces of the layers 912, and a plurality of via holes 914 electrically connected between ground planes for providing desired electrical connections. Additionally, there are passive components 916 connected between the ground planes 906 and 908. More specifically, the ground plane 906 is allowed to be electrically connected to the ground 908 through the passive components 916 only. Similar to the passive component 308 shown in FIG. 3, the passive component 916 shown in FIG. 9 is used for providing a current loop of high frequency signal generated from the TCXO 902, and could be implemented by a resistor or a low AC impedance inductor (i.e., high frequency inductor). Since the composition of the circuit board is well known to those skilled in this art, further explanation is omitted here for the sake of brevity. It should be noted that only the elements pertinent to the present invention are shown. For example, in FIG. 9 and FIG. 10, only ground planes are depicted; however, a skilled person will readily appreciate that the circuit board 920 also includes signal and power traces (not shown) routed on the layers 912 and associated via holes (not shown) in the layers 912 to thereby interconnect circuit components. Moreover, the size and shape of the ground planes 906, 908 and the number and position of the passive components 906 are not meant to be limitations of the present invention.

As one can see, the ground plane 906 on the circuit board 920 is dedicated to the TCXO 902, and is not directly connected to the ground plane 908 commonly used by the GPS IC 904 and the specific-purpose IC 903. That is, the ground plane 906 is electrically connected to the adjacent ground plane 908 through the passive components 916 instead of direct metal contact. In this way, the heat generated by other circuit components, including the GPS IC 906 and the specific-purpose IC 903, is blocked from being transferred from the ground plane 908 to the ground plane 906 due to low thermal conductivity of the passive components 916. As a result, with the gap between the ground plane layout dedicated to the TCXO 902 and the ground plane layout common to the other circuit components, the TCXO 902 can operate at a more stable environment, and the frequency drift is minimized accordingly. In short, one key feature of the above exemplary COB design is to block the dedicated ground plane 906 from being electrically connected to the common ground plane 908 within the same circuit board 920. In this way, the conventional heat transfer path established between the TCXO and the GPS IC due to the common ground plane is completely cut off.

Please note that, based upon above disclosure, the via holes electrically connecting the dedicated ground plane layout of the TCXO to the common ground plane layout of other circuit components are prohibited; otherwise, the TCXO still suffers the thermal disturbance generated from other circuit components.

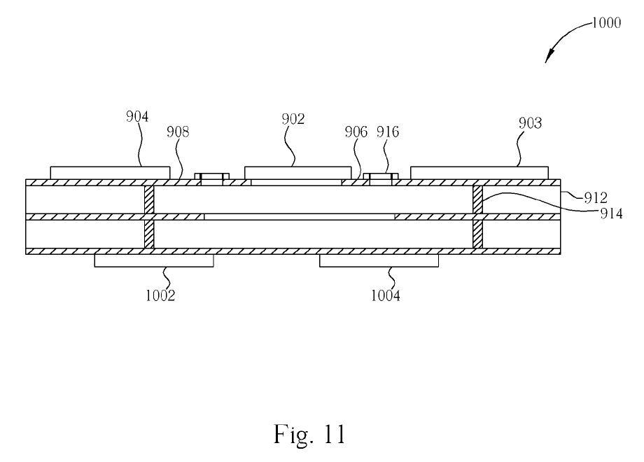

Referring to above disclosure related to the circuit structure of a module design, the ground planes overlapped with the dedicated ground plane of the TCXO can be selectively removed according to design requirements. In addition, as mentioned above, the dedicated ground plane is allowed to have an inner hollow region covered by the TCXO to offer further heat isolation. As to the circuit structure of the COB design, these design options can be selectively applied as well. Furthermore, as shown in FIG. 10, all of the circuit components are mounted on one side of the circuit board 920; however, for certain applications, both sides of a circuit board can be used for carrying desired circuit components. Please refer to FIG. 11, which is an alternative circuit structure 1000 applied to a COB design. Compared with the diagram shown in FIG. 10, the circuit structure 1000 have circuit components, including the TCXO 902, the GPS IC 904, and specific-purpose ICs 903, 1002, 1004 mounted on sides of the same circuit board, wherein one ground plane overlapped with the ground plane 906 in the thickness direction of the circuit board is removed, and the ground plane 906 has an inner hollow region. As the proposed features of providing the ground plane 906 dedicated to the TCXO 902 and using passive components 916 to connected the ground plane 906 and the ground plane 908 commonly used by other circuit components (i.e., the GPS IC 904 and the specific-purpose ICs 903, 1002, 1004) are implemented on the alternative circuit structure 1000, the same objective of minimizing the frequency drift happening to the reference oscillating signal generated from the TCXO 902 is achieved.

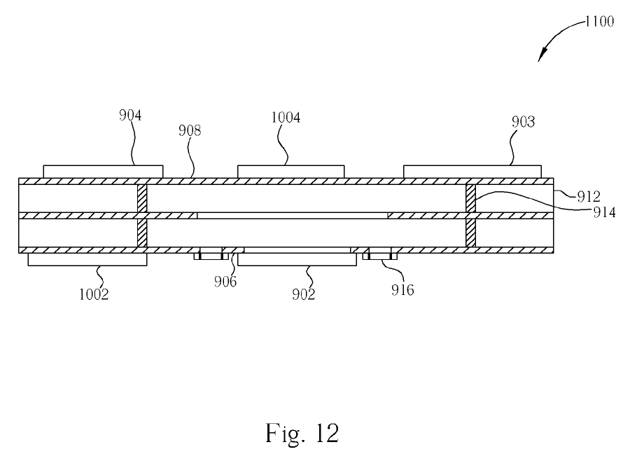

Regarding the COB design, the above embodiments illustrate that the GPS IC 904 and the TCXO 902 are both mounted on the same side of the circuit board. However, provided that the GPS IC 904 is a dominant heat source among the circuit components on the circuit board, the TCXO 902 and the GPS IC 904 can be mounted on different sides of the circuit board to further improve the heat isolation effect. FIG. 12 illustrates yet another alternative circuit structure 1100 applied to a COB design, where the TCXO 902 and the GPS IC 904 are mounted on different sides of the same circuit board. In light of the diagram of FIG. 11, the circuit structure 1100 shown in FIG. 12 is self-explanatory and further description is omitted here for brevity.

Briefly summarized, the present invention applies a novel ground plane layout architecture to a module design or COB design. With the help of the dedicated ground plane layout, the heat dissipated from other circuit components to the oscillator is partially or totally blocked. In this way, the frequency drift of the reference oscillating signal provided by the oscillator could be minimized to thereby improve overall performance of the system implemented according to the module design or COB design. It should be noted that the above embodiments are for illustrative purposes only. That is, after reading above disclosure, a skilled person can readily appreciate that the novel ground plane layout architecture can be applied to any circuit design requiring a highly accurate and stable clock source. Any alternative designs not departing from the spirit of the present invention still fall in the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuit structure, comprising:
a first circuit board, comprising:
a first ground plane layout, comprising at least one ground plane; and
a second ground plane layout, comprising at least one ground plane, wherein the first ground plane layout is not electrically connected to the second ground plane layout within the first circuit board.

2. The circuit structure of claim 1, wherein the first ground plane layout and the second ground plane layout have no direct contact within the first circuit board.

3. The circuit structure of claim 1, further comprising:
a first circuit component, mounted on the first circuit board and electrically connected to the first ground plane layout; and
a second circuit component, mounted on the first circuit board and electrically connected to the second ground plane layout.

4. The circuit structure of claim 3, wherein the first circuit component is an oscillator.

5. The circuit structure of claim 4, wherein the second circuit component is a signal processor of a global navigation satellite system (GNSS), and the oscillator is for providing an oscillating signal associated with operations of the signal processor.

6. The circuit structure of claim 3, wherein the first ground plane layout comprises a ground plane with a hollow region covered by the first circuit component in a thickness direction of the first circuit board.

7. The circuit structure of claim 3, wherein the first circuit board has at least one layer on which no ground plane overlapped with the first ground plane layout in a thickness direction of the first circuit board is disposed.

8. The circuit structure of claim 7, wherein the first circuit board has no ground plane overlapped with the first ground plane layout in the thickness direction of the first circuit board.

9. The circuit structure of claim 3, wherein within the first circuit board, the first ground plane layout is electrically connected to the first circuit component only.

10. The circuit structure of claim 1, further comprising:
a second circuit board, on which the first circuit board is mounted, the second circuit board comprising:
a third ground plane layout, electrically connected to the first ground plane layout, comprising at least one ground plane; and
a fourth ground plane layout, electrically connected to the second ground plane layout, comprising at least one ground layer, wherein the fourth ground plane layout is not electrically connected to the third ground plane layout within the second circuit board.

11. The circuit structure of claim 10, wherein the first ground plane layout is not overlapped with the fourth ground plane layout in a thickness direction of the first circuit board, and the second ground plane layout is not overlapped with third ground plane layout in the thickness direction of the first circuit board.

12. The circuit structure of claim 10, further comprising:
a first circuit component, mounted on the first circuit board and electrically connected to the first ground plane layout; and
a second circuit component, mounted on the first circuit board and electrically connected to the second ground plane layout.

13. The circuit structure of claim 12, wherein the first circuit component is an oscillator.

14. The circuit structure of claim 13, wherein the second circuit component is a signal processor of a global navigation satellite system (GNSS), and the oscillator is for providing an oscillating signal associated with operations of the signal processor.

15. The circuit structure of claim 10, further comprising:
at least one passive component, mounted on the second circuit board, for electrically connecting the third ground plane layout and the fourth ground plane layout.

16. The circuit structure of claim 15, wherein the third ground plane layout is electrically connected to the fourth ground plane layout through passive component(s) mounted on the second circuit board only.

17. The circuit structure of claim 15, wherein the passive component is a resistor or a low AC impedance inductor.

18. A circuit structure, comprising:
a circuit board, comprising:
a first ground plane layout, comprising at least one ground layer; and
a second ground plane layout, comprising at least one ground layer, wherein the first ground plane layout is not electrically connected to the second ground plane within the circuit board; and
at least a passive component, mounted on the circuit board, for electrically connecting the first ground plane layout to the second ground plane layout.

19. The circuit structure of claim 18, wherein the first ground plane layout is electrically connected to the second ground plane layout through passive component(s) mounted on the circuit board only

20. The circuit structure of claim 18, wherein the passive component is a resistor or a low AC impedance inductor.

21. The circuit structure of claim 18, further comprising:
a first circuit component, mounted on the circuit board and electrically connected to the first ground plane layout; and
a second circuit component, mounted on the circuit board and electrically connected to the second ground plane layout.

22. The circuit structure of claim 21, wherein the first circuit component is an oscillator.

23. The circuit structure of claim 22, wherein the second circuit component is a signal processor of a global navigation satellite system (GNSS), and the oscillator is for providing an oscillating signal associated with operations of the signal processor.

24. The circuit structure of claim 23, wherein the signal processor and the oscillator are mounted at different sides of the circuit board.

25. The circuit structure of claim 21, wherein the first ground plane layout has an inner hollow region covered by the first circuit component in a thickness direction of the circuit board.

26. The circuit structure of claim 21, wherein the circuit board has at least one layer on which no ground plane overlapped with the first ground plane layout in a thickness direction of the circuit board is disposed.

27. The circuit structure of claim 26, wherein the circuit board has no ground plane overlapped with the first ground plane layout in the thickness direction of the circuit board is disposed.
